(19) United States
(12) Patent Application Publication
(10) Pub. No.: US 2003/0057569 A1
(43) Pub. Date: Mar. 27, 2003

(54) Semiconductor device

(75) Inventors: Keiichiro Wakamiya, Tokyo (JP); Toshihiro Iwasaki, Tokyo (JP); Michitaka Kimura, Tokyo (JP); Yasumichi Hatanaka, Tokyo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/091,306

(22) Filed: Mar. 6, 2002

(30) Foreign Application Priority Data
Sep. 26, 2001 (JP) 2001-294554

(51) Int. Cl. H01L 23/48; H01L 23/52; H01L 29/40

(52) U.S. Cl. 257/780

(57) ABSTRACT

A semiconductor device is used which is provided with a semiconductor chip having Au bumps on its surface and a chip-mounting substrate having external electrode lands on its chip-mounting face while having external electrode pads on its external connection face and constituted by bonding Au bumps on the semiconductor chip to internal electrode pads on the chip-mounting substrate while turning the semiconductor chip upside down, in which external electrode lands are arranged in areas corresponding to arrangement areas of internal electrode pads at the both sides of the chip-mounting substrate.

### FIELD OF THE INVENTION

The present invention relates to a semiconductor device constituted by boding bumps of a semiconductor chip having the bumps on its surface to a chip-mounting member such as a chip-mounting substrate while turning the semiconductor chip upside down.

### BACKGROUND OF THE INVENTION

FIGS. 7A to 7C show a first example of the semiconductor device of this type and FIGS. 8A and 8B show a second example of the semiconductor device.

First, the semiconductor device of the first example shown in FIGS. 7A to 7C is referred to as the flip-chip type in which a semiconductor chip 1 is turned upside down and mounted on a chip-mounting substrate 2. As shown in FIG. 7A, a plurality of Al (aluminum) pads 3 are formed on the surface (lower face in FIG. 7A) of the semiconductor chip 1 and Au (gold) bumps 4 are formed on each Al pad 3 by means of wire boding. Moreover, to the chip-mounting substrate 2, an internal electrode pad 5 serving as an internal terminal is formed on a chip-mounting face 2a for mounting the semiconductor chip 1 while an external electrode land 6 serving as an external terminal is formed on an external connection face 2b. When the semiconductor chip 1 is mounted, Au bumps 4 on the semiconductor chip 1 are bonded to internal electrode pads 5. Solder balls (not shown) are mounted on the external electrode land 6 when mounting the semiconductor device on a mounting object such as a mounting substrate. Symbol 2c in FIG. 7A to FIG. 8C denotes a via for connecting the internal electrode pad 5 with the external electrode land 6.

In the case of the semiconductor device of the second example shown in FIGS. 8A and 8B, a chip-mounting substrate 7 has a plurality of wiring patterns 8 and 9. As shown in FIG. 8A, to chip-mounting substrate 7, the internal electrode pads 8a and 9a serving as internal terminals are formed every wiring-pattern layers 8 and 9. Au bumps 4 on a semiconductor chip 1 are bonded to internal electrode pads 8a and 9a when the semiconductor chip 1 is mounted. Because the configuration of the semiconductor chip 1 is the same as that of the semiconductor device of the above first example, components provided with same symbols are used and their descriptions are omitted.

In the case of the above semiconductor devices of the first and second examples, it is possible to mount the semiconductor chip 1 on the chip-mounting substrates 2 and 7 only by forming internal electrode pads 5, 8a, and 9a of chip-mounting substrates 2 and 7 in areas corresponding to Au bumps 4 on the semiconductor chip 1.

However, in the case of the semiconductor device of the first example shown in FIGS. 7A to 7C, because a difference is produced between substantial plate thicknesses of the chip-mounting substrate 2, a large difference is produced between crushed amounts of Au bumps 4 as shown in FIG. 7C when mounting the semiconductor chip 1 on the chip-mounting substrate 2 by using ultrasonic thermocompression bonding. That is, as shown in FIGS. 7B and 7C, the crushed amount of Au bumps 4 to be joined to internal electrodes 5 in which the external electrode land 6 is not present in a corresponding area of the external connection face 2b is inevitably decreased compared to Au bumps 4a to be joined to internal electrode pads 5 in which external lands 6 are formed in a corresponding area of the external connection face 2b. As a result, a large difference is produced in junction conditions between Au bumps 4 and internal electrode pads 5 in one semiconductor device and in the latter case, imperfect connection may occur between Au bumps 4 and internal electrode pads 5.

Moreover, the semiconductor device of the second example shown in FIGS. 8A and 8B has the same problem. That is, because a height-directional difference is present between an internal electrode pad (hereafter merely referred to as lower pad 8a) formed on the lower wiring-pattern layer 8 and an internal electrode pad (hereafter merely referred to as upper pad 9a) formed on the upper wiring-pattern layer 9, a large difference is produced between the crushed amounts of Au bumps 4c and 4d to pads 8a and 9a as shown in FIG. 8B. Therefore, imperfect connection may occur between the low lower pad 8a and the Au bump 4d.

### SUMMARY OF THE INVENTION

It is an object of the present invention to provide a semiconductor device capable of uniforming junction conditions between bumps of a semiconductor chip and internal terminals of a chip-mounting member.

According to one aspect of the present invention, there is provided a semiconductor device provided with a semiconductor chip having bumps on its surface and internal terminals on its chip-mounting face while having a chip-mounting member provided with external terminals on its external connection face and constituted by bonding the bumps on the semiconductor chip to internal terminals of the chip-mounting member while turning the semiconductor chip upside down, in which the external terminals are arranged in areas corresponding to arrangement areas of the internal terminals at the both sides of the chip-mounting member.

According to this aspect, thicknesses of the chip-mounting member become the same at portions where bumps of the semiconductor chip are bonded.

According to another aspect of the present invention, there is provided a semiconductor device provided with a semiconductor chip having bumps on its surface and a chip-mounting member having internal terminals on its chip-mounting face while having external terminals on its external connection face and constituted by bonding the bumps on the semiconductor chip to the internal terminals of the chip-mounting member while turning the semiconductor chip upside down, in which the external terminals are arranged in areas corresponding to arrangement areas of the internal terminals at the both sides of the chip-mounting member.

According to this aspect, plate thicknesses of the chip-mounting member become the same at portions where bumps of the semiconductor chip are bonded.

According to still another aspect of the present invention, there is provided a semiconductor device provided with a semiconductor chip having bumps on its surface and a chip-mounting member having a plurality of internal terminals with heights different from each other on its chip-mounting face and constituted by bonding the bumps on the semiconductor chip to the internal terminals of the chip-mounting member while turning the semiconductor chip upside down, in which heights of the bumps are changed in accordance with the heights of the internal terminals so that the chip-mounting member and the semiconductor chip become parallel with each other.

According to the above aspect, it is possible to absorb differences between heights of the internal terminals by changing heights of the bumps.

Other objects and features of this invention will become apparent from the following description with reference to the accompanying drawings.

### BRIEF DESCRIPTION OF THE DRAWINGS

FIGS. 1A to 1C show a configuration of a semiconductor device of a first embodiment of the present invention, in which FIG. 1A is a sectional side view conceptually showing a state in which a semiconductor chip is separate from a chip-mounting member, FIG. 1B is a sectional side view conceptually showing a state in which the semiconductor chip is mounted on the chip-mounting member, and FIG. 1C is a top view conceptually showing the chip-mounting member,

FIGS. 2A to 2C show a configuration of a semiconductor device of a second embodiment of the present invention, in which FIG. 2A is a sectional side view conceptually showing a state in which a semiconductor chip is separate from a chip-mounting member, FIG. 2B is a sectional side view conceptually showing a state in which the semiconductor chip is mounted on the chip-mounting member, and FIG. 2C is a top view conceptually showing the chip-mounting member,

FIGS. 3A to 3C show a configuration of a semiconductor device of a third embodiment of the present invention, in which FIG. 3A is a sectional side view conceptually showing a state in which a semiconductor chip is separate from a chip-mounting member, FIG. 3B is a sectional side view conceptually showing a state in which the semiconductor chip is mounted on the chip-mounting member, and FIG. 3C is a top view conceptually showing the chip-mounting member,

FIGS. 4A and 4B show a configuration of a semiconductor device of a forth embodiment of the present invention, in which FIG. 4A is a sectional side view conceptually showing a state in which a semiconductor chip is separate from a chip-mounting member and FIG. 4B is a sectional side view conceptually showing a state in which the semiconductor chip is mounted on the chip-mounting member,

FIGS. 5A and 5B show a configuration of a semiconductor device of a fifth embodiment of the present invention, in which FIG. 5A is a sectional side view conceptually showing a state in which a semiconductor chip is separate from a chip-mounting member and FIG. 5B is a sectional side view conceptually showing a state in which the semiconductor chip is mounted on the chip-mounting member,

FIG. 6 is a sectional side view showing a modification of the semiconductor devices shown in FIGS. 4 and 5,

FIGS. 7A to 7C show a conventional semiconductor device, in which FIG. 7A is a sectional side view conceptually showing a state in which a semiconductor chip is separate from a chip-mounting member, FIG. 7B is a sectional side view conceptually showing a state in which the semiconductor chip is mounted on the chip-mounting member, and FIG. 7C is a top view conceptually showing the chip-mounting member, and

FIGS. 8A and 8B show a configuration of another conventional semiconductor device, in which FIG. 8A is a sectional side view conceptually showing a state in which a semiconductor chip is separate from a chip-mounting member and FIG. 5B is a sectional side view conceptually showing a state in which the semiconductor chip is mounted on the chip-mounting member.

### DETAILED DESCRIPTIONS

Embodiments of the semiconductor device of the present invention are described below in detail by referring to the accompanying drawings.

First Embodiment,

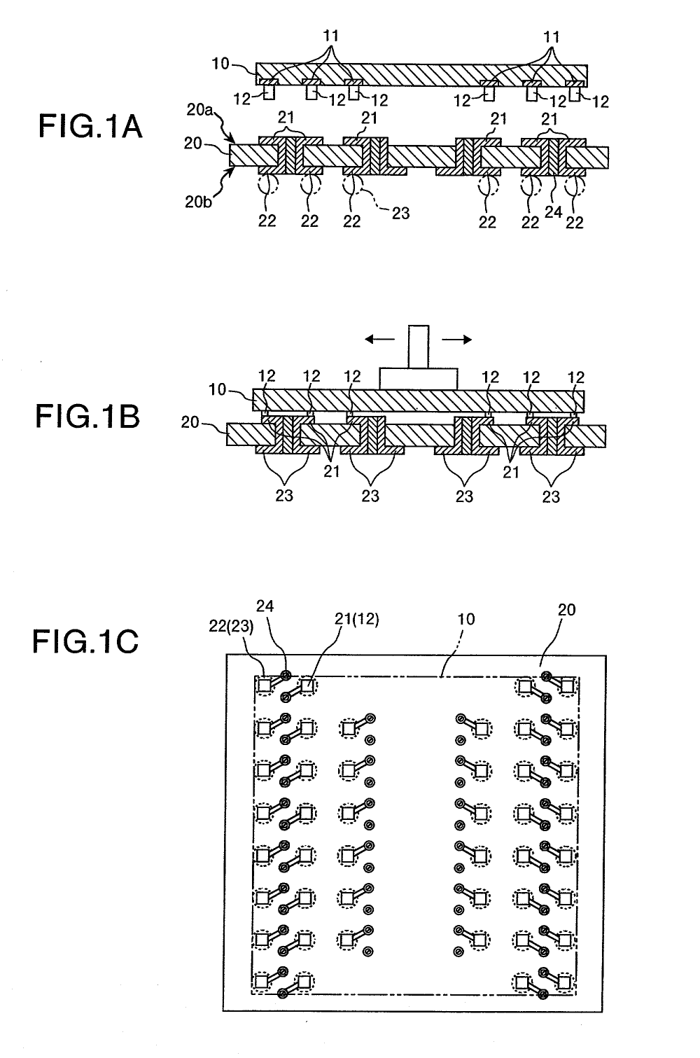

FIGS. 1A to 1C show a semiconductor device that is a first embodiment of the present invention. The semiconductor device shown in FIGS. 1A to 1C is referred to as the flip chip type which is mounted on a chip-mounting substrate (chip-mounting member) 20 made of glass epoxy while turning a semiconductor chip 10 upside down.

A plurality of Al pads 11 are formed on the surface (lower face in FIG. 1A) of the semiconductor chip 10 as shown in FIG. 1A. An Au bump 12 is formed on each Al pad 11 by means of wire bonding.

Internal electrode pads 21 are formed on a chip-mounting face 20a on which the semiconductor chip 10 will be mounted. Each internal electrode pad 21 is a portion serving as an internal terminal which is set to a portion corresponding to the Au bump 12 of the above semiconductor chip 10. It is allowed to use a laminated structure obtained by plating a Cu (copper) foil having a thickness of 18 μm with Ni (nickel) up to a thickness of approx. 5 μm and moreover plating the foil with Au up to a thickness of approx. 0.1 μm as the internal electrode pad 21.

Moreover, the external electrode lands 22 are formed on an external connection face 20b serving as the back of the chip-mounting face 20a on the chip-mounting plate 20. The external electrode lands 22 are portions serving as external terminals that are formed in areas corresponding to arrangement areas of the above internal electrode pads 21 at the both sides of the chip-mounting substrate 20. That is, the first embodiment is constituted so that the area in which internal electrode pads 21 are arranged and the area in which external electrode lands 22 are arranged correspond to each other at the both sides of the chip-mounting substrate 20. It is allowed to use a laminated structure obtained by plating a Cu foil having a thickness of 18 μm with Ni up to a thickness of approx. 5 μm and moreover plating the foil with Au up to a thickness of approx. 0.1 μm as the external electrode land 22 similarly to the case of the above internal electrode land 21. A solder ball 23 is mounted on each external electrode land 22 when mounting a semiconductor device on amounting object such as amounting substrate. Moreover, the external electrode lands 22 are connected with the above internal electrode pads 21 through a via 24 by means of Cu plating. Furthermore, it is not always necessary to arrange the external electrode lands 22 only in areas corresponding to arrangement areas of internal electrode pads 21 at the both sides of the chip-mounting substrate 20 but it is allowed to arrange them in other necessary portions.

As shown in FIG. 1B, in the case of the semiconductor device, each Au bump 12 is bonded to a corresponding internal electrode pad 21 by means of ultrasonic thermocompression bonding while making the Au bumps 12 on the semiconductor chip 10 face to internal electrode pads 21 on the chip-mounting substrate 20 and the semiconductor chip 10 is mounted on the chip-mounting substrate 20.

In this case, according to the semiconductor device of the first embodiment, the external electrode lands 22 are arranged in areas corresponding to arrangement areas of internal electrode pads 21 at the both sides of the chip-mounting substrate 20 as described above. Therefore, substantial plate thichnesses of the chip-mounting substrate 20 become the same at portions where Au bumps 12 on the semiconductor chip 10 are bonded. That is, at portions where Au bumps 12 on the semiconductor chip 10 are bonded, the substantial thickness of the chip-mounting substrate 20 becomes equal to a value obtained by adding the thickness of the internal electrode pad 21 and the thickness of the external electrode land 22. Therefore, when using ultrasonic thermocompression bonding, a load is uniformly added to Au bumps 12 to be joined to internal electrode pads 21 and crushed amounts of bumps 12 also become uniform. As a result, in one semiconductor device, junction conditions between Au bumps 12 and internal electrode pads 21 become the same and it is possible to improve the quality of the semiconductor device without an anxiety that imperfect connection may occur at a specific portion.

Second embodiment,

In the case of the above first embodiment, external terminals are arranged in areas corresponding to arrangement areas of internal terminals at the both sides of a chip-mounting member. In the case of a second embodiment, however, external terminals are arranged outside of areas corresponding to arrangement areas of internal terminals at the both sides of a chip-mounting member.

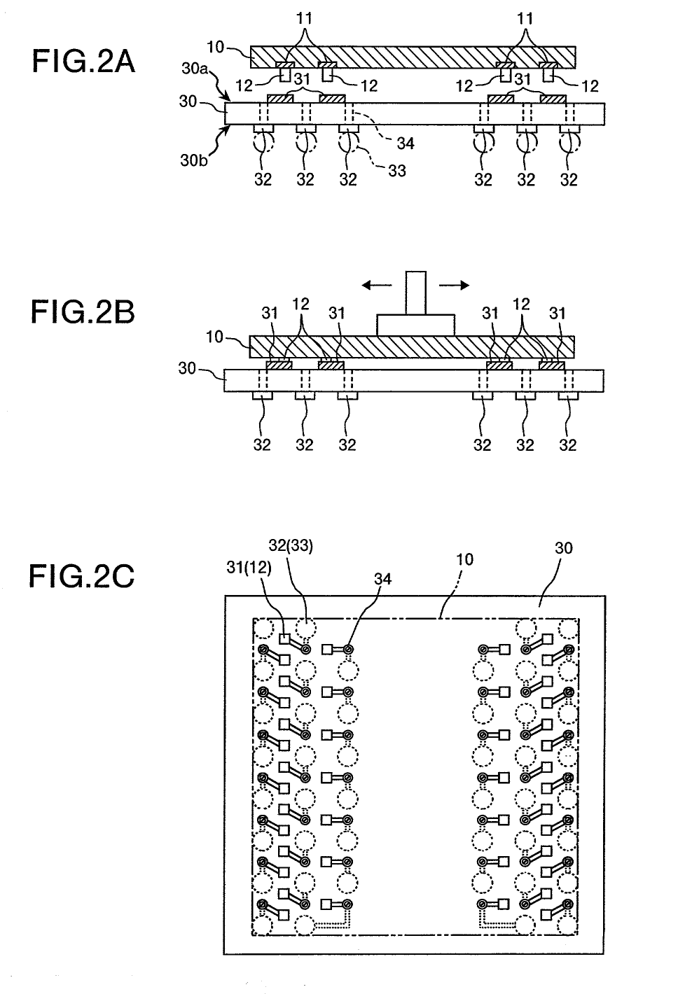

FIGS. 2A to 2C show a semiconductor device that is the second embodiment of the present invention. The semiconductor device shown in FIGS. 2A to 2C is referred to as the flip chip type similarly to the first embodiment which is mounted on a chip-mounting substrate (chip-mounting member) 30 made of glass epoxy while turning a semiconductor chip 10 upside down.

As shown in FIG. 2A, a plurality of Al pads 11 are formed on the surface (lower face in FIG. 2A) of the semiconductor chip 10 and an Au bump 12 is formed on each Al pad 11 by means of wiring bonding.

Internal electrode pads 31 are formed on the chip-mounting face 30a of the chip-mounting substrate 30 for mounting the semiconductor chip 10. Internal electrode pads 31 are portions serving as internal terminals which are arranged in portions corresponding to Au bumps 12 on the above semiconductor chip 10. It is allowed to use a laminated structure obtained by plating a Cu foil having a thickness of 18 μm with Ni up to a thickness of approx. 5 μm and moreover plating the foil with Au up to a thickness of approx. 0.1 μm as each internal electrode pad 31.

Moreover, external electrode lands 32 are formed on an external connection face 30b serving as the back of the chip-mounting face 30a on the chip-mounting substrate 30. External electrode lands 32 are portions serving as external terminals and are arranged outside of areas corresponding to arrangement areas of internal electrode pads 31 at the both sides of the chip-mounting substrate 30 as shown in FIGS. 2B and 2C. That is, the second embodiment is constituted so that areas in which internal electrode pads 31 are arranged and areas in which external electrode lands 32 are arranged are shifted from each other at the both sides of the chip-mounting substrate 30. It is allowed to use a laminated structure obtained by plating a Cu foil having a thickness of 18 μm with Ni up to a thickness of approx. 5 μm and moreover plating the foil with Au up to a thickness of approx. 0.1 μm similarly to the case of the above internal electrode pad 31. A solder ball 33 is mounted on the external electrode lands 32 when mounting a semiconductor device on a mounting object such as a mounting substrate. Moreover, the external electrode lands 32 are connected with internal electrode pads 31 through a via 34 by means of Cu plating similarly to the case of the first embodiment.

As shown in FIG. 2B, in the case of the semiconductor device, each Au bump 12 is bonded to the corresponding internal electrode pad 31 by means of ultrasonic thermocompression bonding while making Au bumps 12 on the semiconductor chip 10 face to internal electrode pads 31 on the chip-mounting substrate 30 and the semiconductor chip 10 is mounted on the chip-mounting substrate 30.

In this case, according to the semiconductor device of the second embodiment, because external electrode lands 32 are arranged outside of areas corresponding to arrangement areas of internal electrode pads 31 at the both sides of the chip-mounting substrate 30 as described above, substantial thicknesses of the chip-mounting substrate 30 become the same at portions where Au bumps 12 on the semiconductor chip 10 are bonded. That is, at portions where Au bumps 12 on the semiconductor chip 10 are bonded, the substantial thickness of the chip-mounting substrate 30 becomes equal to a value obtained by adding plate thicknesses of internal electrode pads 31. Therefore, when using ultrasonic thermocompression bonding, a load is uniformly applied to Au bumps 12 to be joined to internal electrode pads 31 and crushed amounts of the bumps also become uniform. As a result, in one semiconductor device, junction conditions between Au bumps 12 and internal electrode pads 31 become the same and it is possible to improve the quality of the semiconductor device without an anxiety that imperfect connection may occur at a specific portion.

Third Embodiment,

In the case of the above first embodiment, external terminals are arranged in areas corresponding to arrangement areas of internal terminals at the both sides of a chip-mounting member. In the case of a third embodiment, however, dummy terminals are formed outside of arrangement areas of external terminals on the external connection face of a chip-mounting member but inside of areas corresponding to arrangement areas of internal terminals at the both sides of the chip-mounting member.

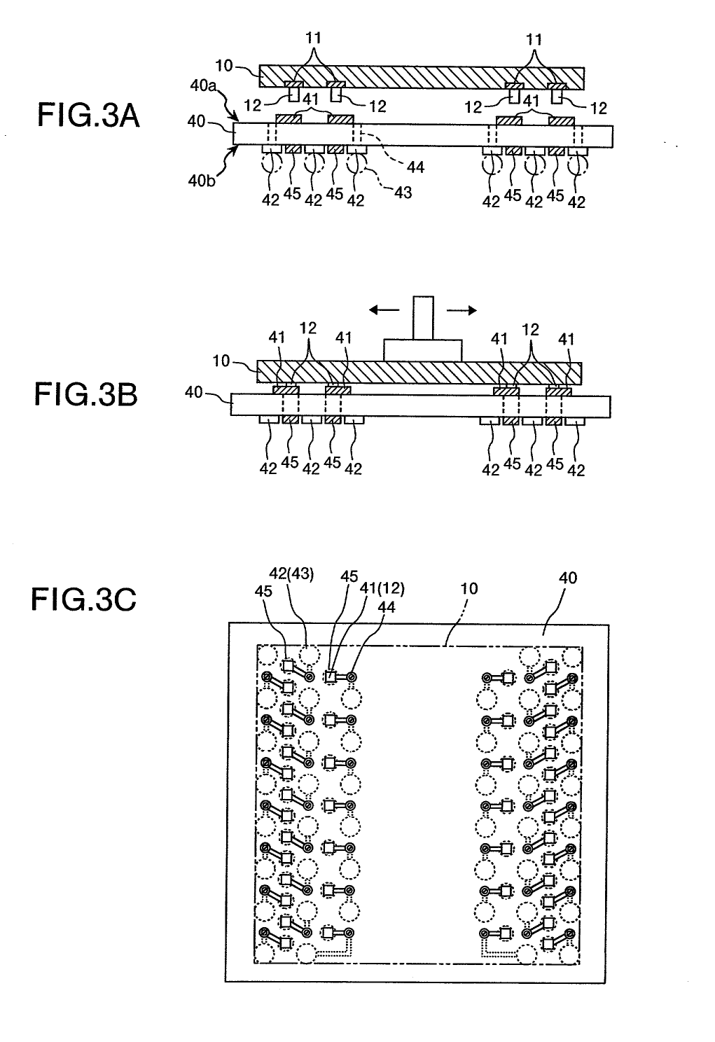

FIGS. 3A to 3C show a semiconductor device that is the third embodiment of the present invention. The semiconductor device shown in FIGS. 3A to 3C is referred to as the flip chip type which is mounted on a chip-mounting substrate (chip-mounting member) made of glass epoxy while turning a semiconductor chip 10 upside down similarly to the case of the first embodiment.

As shown in FIG. 3A, a plurality of Al pads 11 are formed on the surface (lower face in FIG. 3A) of the semiconductor chip 10 and an Au bump 12 is formed on each Al pad 11 by means of wire bonding.

Internal electrode pads 41 are formed on the chip-mounting face 40a of a chip-mounting substrate 40 for mounting the semiconductor chip 10. Internal electrode pads 41 are portions serving as internal terminals and are arranged at portions corresponding to Au bumps 12 on the semiconductor chip 10. It is allowed to use a laminated structure obtained by plating a Cu foil having a thickness of 18 μm with Ni up to a thickness of approx. 5 μm and moreover plating the foil with Au up to a thickness of approx. 0.1 μm as the internal electrode pad 41 similarly to the case of the first embodiment.

Moreover, external electrode lands 42 and dummy lands 45 are formed on an external connection face 40b serving as the back of the chip-mounting face 40a of the chip-mounting substrate 40.

External electrode lands 42 are portions serving as external terminals and are arranged outside of areas corresponding to arrangement areas of internal electrode pads 41 at the both sides of the chip-mounting substrate 40 as shown in FIGS. 3B and 3C. That is, the third embodiment is constituted so that areas in which internal electrode pads 41 are arranged and areas in which external electrode lands 42 are arranged are shifted from each other at the both sides of the chip-mounting substrate 40. It is allowed to use a laminated structure obtained by plating a Cu foil having a thickness of 18 μm with Ni up to a thickness of approx. 5 μm and moreover plating the foil with Au up to a thickness of approx. 0.1 μm as each external electrode land 42 similarly to the case of the above internal electrode pads 41. A solder ball 43 is mounted on the external electrode lands 42 when mounting a semiconductor device on a mounting object such as a mounting substrate. Moreover, internal electrode pads 41 are connected with external electrode lands 42 through a via 44 by means of Cu plating similarly to the case of the first embodiment.

However, dummy lands 45 are arranged in areas corresponding to arrangement areas of internal electrode pads 41 at the both sides of the chip-mounting substrate 40. That is, the third embodiment is constituted so that areas in which internal electrode pads 41 are arranged and areas in which dummy lands 45 are arranged correspond to each other at the both sides of the chip-mounting substrate 40. It is allowed that each dummy land 45 is made of any material or constituted by any structure. In this case, it is not always necessary to constitute each dummy land 45 by a conductor or it is allowed that dummy lands 45 have a plate thickness different from that of the external electrode land 42 as long as dummy lands 45 have the same plate thickness. The solder ball 43 is not mounted on dummy lands 45 even when mounting a semiconductor device on a mounting object such as a mounting substrate. Moreover, dummy lands 45 and internal electrode pads 41 are not connected each other or dummy lands 45 and external electrode lands 42 are not connected each other.

As shown in FIG. 3B, in the case of the semiconductor device, each Au bump 12 is bonded to the corresponding internal electrode pad 41 by means of ultrasonic thermocompression bonding while making Au bumps 12 on the semiconductor chip 10 face to internal electrode lands 41 on the chip-mounting substrate 40 and the semiconductor chip 10 is mounted on the chip-mounting substrate 40.

In this case, according to the semiconductor device of the third embodiment, dummy lands 45 are arranged in areas corresponding to arrangement areas of internal electrode pads 41 at the both sides of the chip-mounting substrate 40 as described above. Therefore, substantial plate thicknesses of the chip-mounting substrate 40 become the same at portions where Au bumps 12 on the semiconductor chip 10 are bonded. That is, at portions where Au bumps 12 on the semiconductor chip 10 are bonded, each substantial plate thickness of the chip-mounting substrate 40 becomes equal to a value obtained by adding the plate thickness of the internal electrode pad 41 and the plate thickness of the dummy land 45. Therefore, when using ultrasonic thermocompression bonding, a load is uniformly applied to Au bumps 12 to be joined to internal electrode pads 41 and crushed amounts of the bumps also become uniform. As a result, in one semiconductor device, junction conditions between Au bumps 12 and internal electrode pads 41 become the same and it is possible to improve the quality of the semiconductor device without an anxiety that imperfect connection may occur in a specific portion.

In the case of the above third embodiment, external electrode lands 42 are arranged outside of areas corresponding to arrangement areas of internal electrode pads 41 at the both sides of the chip-mounting substrate 40 while dummy lands 45 are arranged in all areas corresponding to arrangement areas of internal electrode pads 41 at the both sides of the chip-mounting substrate 40′. However, the present invention is not restricted to the above case. For example, it is allowed to arrange external electrode lands 42 in any areas on the external connection face 40b of the chip-mounting substrate 40 and outside of arrangement areas of external electrode lands 42, form dummy lands 45 only in areas corresponding to arrangement areas of internal electrode pads 41 at the both sides of the chip-mounting substrate 40. In this case, however, it is necessary to use dummy lands 4,5 having the same thickness as external electrode lands 42.

Forth Embodiment,

The above first embodiment is a semiconductor device to which a chip-mounting member having internal terminals on its chip-mounting face while having external terminals on its external connection face is applied. However, a forth embodiment is a semiconductor device to which a chip-mounting substrate having a plurality of internal terminals with heights different from each other on its chip-mounting face is applied.

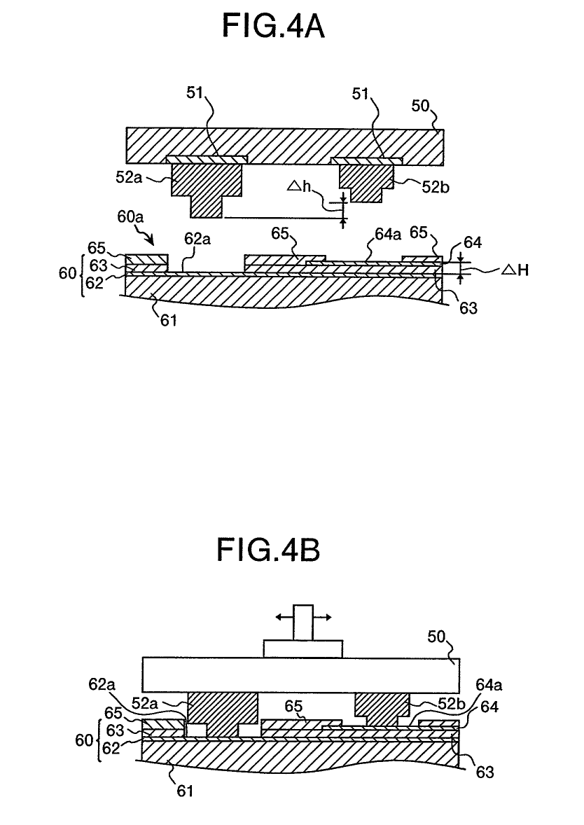

FIGS. 4A and 4B show the semiconductor device of the forth embodiment of the present invention. The semiconductor device shown in FIGS. 4A and 4B is referred to as the flip chip type similarly to the first embodiment, which is mounted on a chip-mounting substrate (chip-mounting member) 60 made of glass epoxy while turning a semiconductor chip 50 upside down.

A chip-mounting substrate 60 applied to the forth embodiment is a multilayer substrate having a first wiring-pattern layer 62 made of Cu on its first interior core 61 and having a second interior core 63 on the first wiring-pattern layer 62 and moreover having a second wiring-pattern layer 64 made of Cu on the second interior core 63. Furthermore, a solder resist layer 65 is formed on the second wiring-pattern layer 64. In the case of the chip-mounting substrate 60, internal electrode pads 62a and 64a having heights different from each other are formed on a chip-mounting face 60a for mounting the semiconductor chip 50. That is, the chip-mounting substrate 60 is provided with a first internal-electrode pad 62a constituted by exposing the first wiring-pattern layer 62 to the outside and a second internal-electrode pad 64a constituted by exposing the second wiring-pattern layer 64 to the outside. These first and second internal-electrode pads 62a and 64a are portions serving as internal terminals and arranged at portions corresponding to Au bumps 52a and 52b of a semiconductor chip 50 to be described later.

Moreover, as shown in FIG. 4A, a plurality of Al pads 51 are formed on the surface (lower face in FIG. 4A) of the semiconductor chip 50 and Au bumps 52a and 52b are provided for each Al pad 51. Au bumps 52a and 52b are formed by means of wire bonding and are different in height in accordance with the first and second internal-electrode pads 62a and 64a. Specifically, Au bump (hereafter referred to as first Au bump 52a) corresponding to the first internal-electrode pad 62a having a small height is increased in the height from the surface of the semiconductor chip 50 while Au bump (hereafter referred to as second Au bump 52b) corresponding to the second internal-electrode pad 64a having a large height is decreased in the height from the surface of the semiconductor chip 50. The different Δh between the heights of the first Au bump 52a and second Au bump 52b is set so as to be equal to the difference ΔH between the heights of the first internal-electrode pad 62a and second internal-electrode pad 64a.

As shown in FIG. 4B, in the case of the semiconductor device, Au bumps 52a and 52b are bonded to their corresponding internal-electrode pads 62a and 64a by means of ultrasonic thermocompression wire bonding while making the first and second Au bumps 52a and 52b on the semiconductor chip 50 face to the first and second internal-electrode pads 62a and 64a on the chip-mounting substrate 60 and the semiconductor chip 50 is mounted on the chip-mounting substrate 60.

In this case, according to the semiconductor device of the forth embodiment, the height of the first Au bump 52a corresponding to the first internal-electrode pad 62a having a small height is increased while the height of the second Au bump 52b corresponding to the second internal-electrode pad 64a having a large height is decreased and moreover, the difference Δh between the heights of the first Au bump 52a and second Au bump 52b is set so as to be equal to the difference ΔH between the heights of the first internal-electrode pad 62a and second internal-electrode pad 64a. Therefore, by mounting the semiconductor chip 50 on the chip-mounting substrate 60, all Au bumps 52a and 52b contact their corresponding internal-electrode pads 62a and 64a while the semiconductor chip 50 and the chip-mounting substrate 60 become parallel with each other. Thereby, when using ultrasonic thermocompression bonding, a load is uniformly applied to Au bumps 52a and 52b to be joined to internal electrode pads 62a and 64a and crushed amounts of the Au bumps 52a and 52b become uniform. Therefore, in one semiconductor device, junction conditions between Au bumps 52a and 52b on one hand and internal-electrode pads 62a and 64a on the other become the same and it is possible to improve the quality of the semiconductor device without an anxiety that imperfect connection may occur in a specific portion.

In the case of the above forth embodiment, though a chip-mounting substrate having two internal-electrode pads with heights different from each other is described as a chip-mounting member, it is also possible to apply the present invention to a chip-mounting substrate having three or more internal-electrode pads with heights different from each other.

Fifth Embodiment,

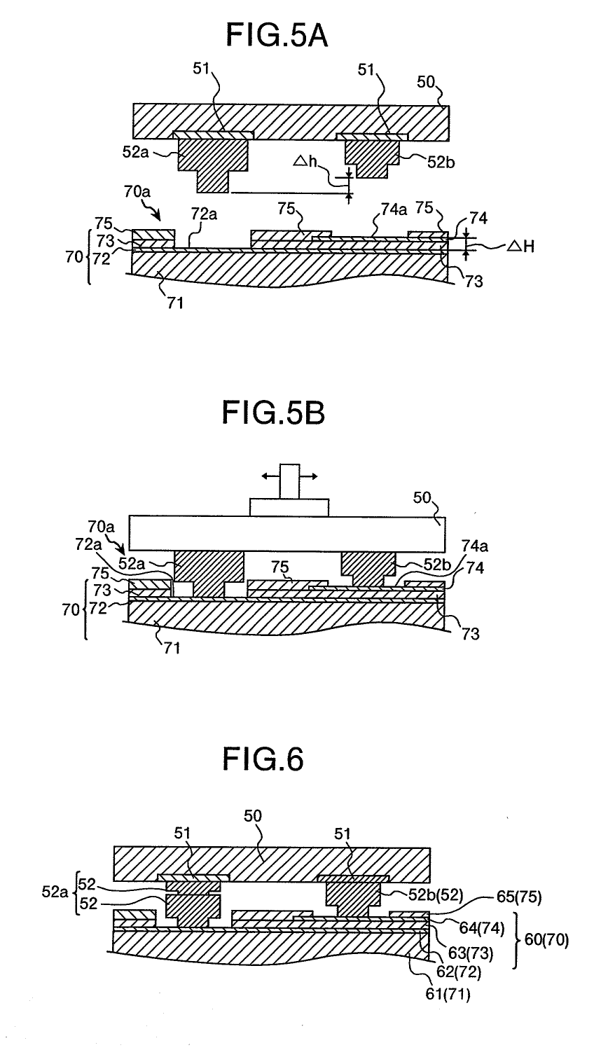

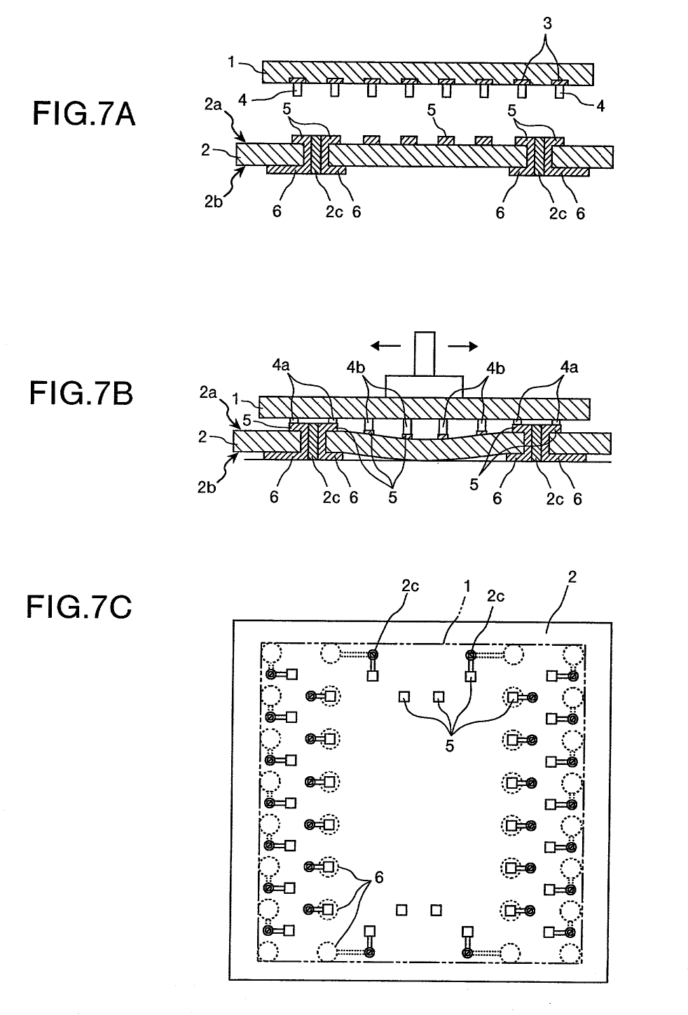

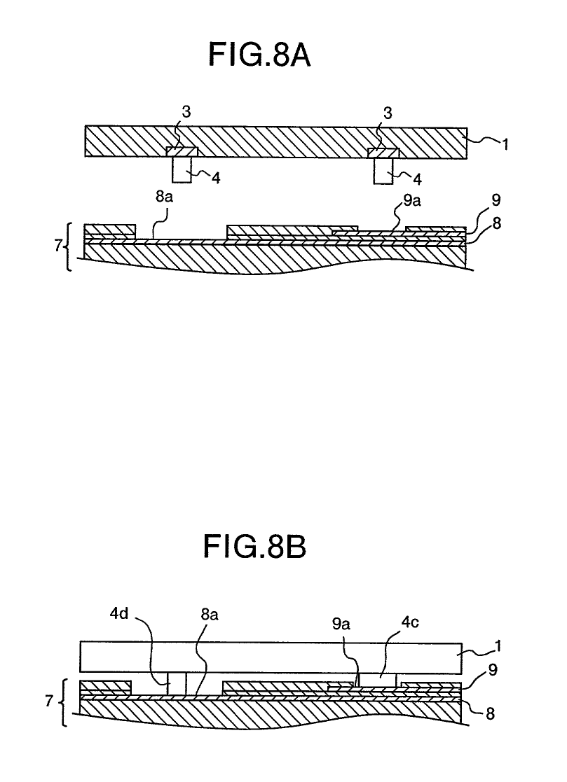

In the case of the forth embodiment, a chip-mounting substrate is described as a chip-mounting member. However, it is also possible to use a chip-mounting-type semiconductor chip as a chip-mounting member like the case of a fifth embodiment shown in FIG. 5.

That is, a chip-mounting-type semiconductor chip 70 serving as a chip-mounting member in the fifth embodiment has a first wiring-pattern layer 72 made of Al or the like on a first insulating layer 71 and a first insulating protective film 73 on the first wiring-pattern layer 72 and moreover has a second wiring-pattern layer 74 made of Al or the like on the first insulating protective film 73. A second insulating protective film 75 is further formed on the second wiring-pattern layer 74. In the case of the chip-mounting-type semiconductor chip 70, internal-electrode pads 72a and 74a with heights different from each other are formed on a chip-mounting face 70a for mounting the semiconductor chip 50. That is, the chip-mounting-type semiconductor chip 70 is provided with the first internal-electrode pad 72a constituted by exposing the first wiring-pattern layer 72 to the outside and the second internal-electrode pad 74a constituted by exposing the second wiring-pattern layer 74 to the outside. These first and second internal-electrode pads 72a and 74a are portions serving as internal terminals and are arranged at portions corresponding to Au bumps 52a and 52b on the semiconductor chip 50 to be described later.

Moreover, as shown in FIG. 5A, a plurality of Al pads 51 are formed on the surface (lower face in FIG. 5A) of the semiconductor chip 50 to be mounted on the above chip-mounting-type semiconductor chip 70 and Au bumps 52a and 52b are formed on each Al pad 51. Au bumps 52a and 52b are formed by means of wiring bonding and are different from each other in height in accordance with the above first and second internal-electrode pads 72a and 74a. Specifically, the first Au bump 52 corresponding to the first internal-electrode pad 72a having a small height is increased in the height from the surface of the semiconductor chip 50 while the second Au bump 52b corresponding to the second internal-electrode pad 74a having a large height is decreased in the height from the surface of the semiconductor chip 50. The difference Δh between the heights of the first Au bump 52a and second Au bump 52b is set so as to be equal to the difference ΔH between the heights of the first internal-electrode pad 72a and second internal-electrode pad 74a.

As shown in FIG. 5B, in the case of the semiconductor device, Au bumps 52a and 52b are bonded to their corresponding internal-electrode pads 72 and 74a by means of wiring bonding while making the first and second Au bumps 52a and 52b on the semiconductor chip 50 face to the first and second internal-electrode pads 72a and 74a on the chip-mounting-type semiconductor chip 70 and the semiconductor chip 50 is mounted on the chip-mounting-type semiconductor chip 70 to constitute a chip-on-chip-type semiconductor device.

In this case, according to the semiconductor device of the fifth embodiment, the height of the first Au bump 52a corresponding to the first internal-electrode pad 72a having a small height is increased while the height of the second Au bump 52b corresponding to the second internal-electrode pad 74a having a large height is decreased and moreover, the difference Δh between the heights of the first Au bump 52a and second Au bump 52b is set so as to be equal to the difference ΔH between the heights of the first internal-electrode pad 72a and second internal-electrode pad 74a. Therefore, by mounting the semiconductor chip 50 on the chip-mounting-type semiconductor chip 70, all Au bumps 52a and 52b contact their corresponding internal-electrode pads 72a and 74a while the semiconductor chip 50 and chip-mounting-type semiconductor chip 70 become parallel with each other. Thereby, when using ultrasonic thermocompression bonding, a load is uniformly applied to Au bumps 52a and 52b to be joined to internal-electrode pads 72a and 74a and crushed amounts of the bumps also become uniform. Therefore, in one semiconductor device, junction conditions between Au bumps 52a and 52b on one hand and internal-electrode pads 72a and 74a on the other become the same and it is possible to improve the quality of the semiconductor device without an anxiety that imperfect connection may occur in a specific portion.

In the case of the above fifth embodiment, a chip-mounting-type semiconductor chip having two internal-electrode pads with heights different from each other is described as a chip-mounting member. However, it is also possible to apply the present invention to a chip-mounting-type semiconductor chip having three or more internal-electrode pads with heights different from each other.

Moreover, in the case of the above forth and fifth embodiments, it is allowed to change heights of Au bumps 52a and 52b in accordance with the overlapped number of predetermined unit bumps 52 as shown by the modification in FIG. 6. For example, it is also allowed to form an Au bump 52a having a large height by overlapping two unit bumps 52 while forming Au bumps 52b having a small height by overlapping one unit bump 52. According to the above modification, because it is possible to easily change heights of Au bumps 52a and 52b in accordance with the number of wire-bonding times for the Al pad 51, there is not an anxiety that operations are complicated when fabricating the semiconductor devices of the above forth and fifth embodiments and it is possible to easily embody them.

As described above, according to one aspect of the present invention, because plate thicknesses of a chip-mounting member become the same at portions for bonding bumps on a semiconductor chip, it is possible to uniform junction conditions between bumps on the semiconductor chip and internal terminals on the chip-mounting member.

According to another aspect of the present invention, because plate thicknesses of a chip-mounting member become the same at portions for bonding bumps on a semiconductor chip, it is possible to uniform junction conditions between bumps on the semiconductor chip and internal terminals on the chip-mounting member.

According to still another aspect of the present invention, because plate thicknesses of a chip-mounting member become the same at portions for bonding bumps on a semiconductor chip, it is possible to uniform junction conditions between bumps on the semiconductor chip and internal terminals on the chip-mounting member.

According to still another aspect of the present invention, because the difference between the heights of internal terminals can be absorbed by changing heights of bumps, it is possible to uniform junction conditions between bumps on the semiconductor chip and internal terminals on the chip-mounting member.

According to still another aspect of the present invention, because heights of bumps can be easily changed, there is not an anxiety that semiconductor-device-fabricating operations are complicated.

According to still another aspect of the present invention, because a semiconductor chip can be mounted on a multilayer substrate by absorbing the difference between heights of internal terminals, it is possible to uniform the junction condition between the multilayer substrate and the semiconductor chip in a semiconductor device having the semiconductor chip on the multilayer substrate.

According to still another aspect of the present invention, because semiconductor chips can be superimposed each other by absorbing the difference between heights of internal terminals, it is possible to embody a chip-on-chip-type semiconductor device in which junction conditions are uniformed.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor chip having bumps on its surface and a chip-mounting member having internal terminals on its chip-mounting face while having external terminals on its external connection face and constituted by bonding the bumps on the semiconductor chip to internal terminals of the chip-mounting member while turning the semiconductor chip upside down, wherein
the external terminals are formed in areas corresponding to arrangement areas of the internal terminals at the both sides of the chip-mounting member.

2. A semiconductor device comprising:
a semiconductor chip having bumps on its surface and a chip-mounting member having internal terminals on its chip-mounting face while having external terminals on its external connection face and constituted by bonding the bumps on the semiconductor chip to internal terminals of the chip-mounting member while turning the semiconductor chip upside down, wherein
the external terminals are formed outside of areas corresponding to arrangement areas of the internal terminals at the both sides of the chip-mounting member.

3. The semiconductor device according to claim 1, wherein dummy terminals are formed outside of arrangement areas of the external terminals on the external connection face of the chip-mounting member but inside of areas corresponding to arrangement areas of the internal terminals at the both sides of the chip-mounting member.

4. A semiconductor device comprising:
a semiconductor chip having bumps on its surface and a chip-mounting member having a plurality of internal terminals with heights different from each other on its chip-mounting face and constituted by bonding the bumps on the semiconductor chip to the internal terminals of the chip-mounting member while turning the semiconductor chip upside down, wherein
heights of the bumps are changed in accordance with heights of the internal terminals so that the chip-mounting member and the semiconductor chip are parallel with each other.

5. The semiconductor device according to claim 4, wherein heights of the bumps are changed in accordance with the overlapped number of the bumps.

6. The semiconductor device according to claim 4, wherein the chip-mounting member is a multilayer substrate having a plurality of wiring layers and the internal terminals on the wiring layers.

7. The semiconductor device according to claim 4, wherein the chip-mounting member is a chip-mounting-type semiconductor chip having a plurality of wiring layers and the internal terminals on the wiring layers.
